(19) United States
(12) Patent Application Publication
(10) Pub. No.: US 2005/0254258 A1
(43) Pub. Date: Nov. 17, 2005

(54) Light emitting diode module and a flat panel display provided with the same

(75) Inventor: Jong-Seo Lee, Gyeonggi-do (KR)

Correspondence Address: PATENT LAW GROUP LLP, 2635 NORTH FIRST STREET, SUITE 223, SAN JOSE, CA, 95134, US

(73) Assignee: Samsung Electronics Co., LTD.

(21) Appl. No.: 11/124,473

(22) Filed: May 4, 2005

(30) Foreign Application Priority Data
May 7, 2004 (KR) 10-2004-0032181

(51) Int. Cl. H01L 33/00

(52) U.S. Cl. 362/612; 362/555; 362/613

(57) ABSTRACT

There is disclosed a light emitting diode module capable of being used as a line light source and a planar light source and a flat panel display using the same. The flat panel display includes a panel unit displaying images and a backlight assembly. The backlight assembly includes a light emitting diode module supplying a light to the panel unit and guides the light to the panel unit. The light emitting diode module includes a plurality of light emitting diodes that emits light and a package that encloses the light emitting diodes. The package has a light emitting surface providing a passage of the light from the light emitting diodes and has a plurality of gratings formed thereon.

### CROSS-REFERENCE TO RELATED APPLICATIONS

The present application claims priority to Korean patent application No. 2004-0032181 filed in the Korean Intellectual Property Office on May 7, 2004, the entire contents of which are herein incorporated by reference in their entirety.

### BACKGROUND OF THE INVENTION

(a) Field of the Invention

The present invention relates to a light emitting diode module (LED module) and a flat panel display provided with the same, and more particularly, to an LED module capable of being used as a line light source and a planar light source, and a flat panel display provided with the same.

(b) Description of the Related Art

Recently, with the rapid development of semiconductor technology, the demand for a small-size and lightweight flat panel display but having a better performance has increased.

Among the flat panel displays, a liquid crystal display (LCD) has the merits of small size, light and lower power consumption. Therefore, much attention has been paid to the LCD as an alternative to the existing cathode ray tube. Nowadays, LCD is widely used for almost all information processing apparatuses requiring display devices.

In a typical LCD, a specific molecular alignment is changed into another molecular alignment by applying a voltage, and a change of optical characteristics of a liquid crystal cell such as birefringence, optical rotary power, dichroism, and optical scattering are converted into a visual change. Thus, information is displayed using an optical modulation of the liquid crystal cells in the LCD.

Since an LCD is a passive device which cannot emit light for itself, the backlight unit is indispensable to the LCD to supply a light source. In the case of a medium or large-sized LCD such as a monitor and a TV, a lamp is used as a backlight. The lamp has not only large power consumption but also has undesired influence on the characteristics of the LCD panel caused by the discharge of heat. Also, since a lamp is conventionally a stick type, there is a problem in that the lamp is not only easily affected by impact but also the display quality comes to be poor due to large temperature deviation of each part.

On the other hand, a light emitting diode (LED) is used as a backlight in a small-size LCD in mobile products such as a cellular phone. Since the LED is a semiconductor device, there are advantages of longer durability, faster lighting, lower power consumption, high shock resistance, and suitability to miniaturization. Thus, when an LED having these advantages is applied to a medium or large-sized LCD, the above-described problems can be solved. That is, by changing the LED of a point light source into a line light source or a planar light source, the LED could have been gradually applied in medium-sized LCD products or large-sized LCD products.

However, since the LED has a limit of light emitting angle due to the unique characteristics thereof, there is a weak point that a light is not transferred from the LED to all directions. Specifically, in the case of LCD products using three kinds of LEDs such as red (R), green (G), and blue (B), there is a problem in that the loss of light increases due to light reflection and dark spots are formed between LEDs due to the limit of light emitting angle.

### SUMMARY OF THE INVENTION

The present invention is contrived to solve the above problems and the present invention provides an LED module, which can be simply used as a line light source or a planar light source and has minimized loss of light, and a flat panel display provided with the same.

According to the present invention, a flat panel display includes a panel unit displaying one or more images, and a backlight assembly including an LED module supplying a light to the panel unit and guiding the light to the panel unit. The LED module includes a plurality of light emitting diodes that emits light and a package that encloses the LEDs. The package has a light emitting surface providing a passage of the light from the LEDs and has a plurality of gratings formed thereon.

Preferably, the flat panel display further comprises a reflecting layer formed on at least one of the surfaces of the package adjacent to the light emitting surface of the package.

More preferably, the flat panel display further comprises a reflecting layer formed on a surface of the package facing the light emitting surface of the package.

Preferably, the flat panel display further comprises a diffusion layer formed on inner or outer surface of the light emitting surface of the package.

More preferably, the flat panel display comprises an index matching member and a light guiding plate (LGP). The index matching member is coated on an outer surface of the light emitting surface of the package. The light guiding plate is disposed adjacent to the index matching member.

Preferably, a refractive index n₃ of the index matching member satisfies a relation of (n₁+n₂)/2<n₃≦n₂. Here, n₁ is a refractive index of air and n₂ is a refractive index of the LGP.

The refractive index of the index matching member is preferably in the range of about 1.4 to about 1.5.

The plurality of LEDs can be arrayed in a line.

The plurality of LEDs can be arrayed in a matrix.

Preferably, the backlight assembly further includes a diffusing plate disposed over the LED module.

The panel unit can be a liquid crystal panel unit.

The present invention provides the LED module including a plurality of LEDs that emits light and a package that encloses the LEDs. The package has a light emitting surface providing a passage of the light from the LEDs and has a plurality of gratings formed thereon.

Preferably, the LED module further comprises a reflecting layer formed on at least one of surfaces of the package adjacent to the light emitting surface of the package.

More preferably, the LED module further comprises a reflecting layer formed on a surface of the package facing the light emitting surface of the package.

Preferably, the LED module further comprises a diffusion layer formed on inner or outer surface of the light emitting surface of the package.

The plurality of LEDs can be arrayed in a line in the LED module according to the present invention.

The plurality of LEDs can be arrayed in a matrix in the LED module according to the present invention.

### BRIEF DESCRIPTION OF THE DRAWINGS

The above and other features of the present invention will become more apparent by describing in detail exemplary embodiments thereof with reference to the attached drawings in which:

FIG. 1 is an exploded perspective view of a flat panel display provided with an LED module according to a first embodiment of the present invention;

FIG. 2 is a schematic diagram of an LED module according to the first embodiment of the present invention;

FIG. 3 is a rear perspective view of a part of a flat panel display provided with an LED module according to a second embodiment of the present invention;

FIG. 4 is an exploded perspective view of a flat panel display provided with an LED module according to a third embodiment of the present invention.

FIG. 5 is a perspective view of an assembled flat panel display provided with an LED module according to the third embodiment of the present invention.

FIG. 6 is a cross-sectional view taken along line AA of FIG. 5;

FIG. 7 is an exploded perspective view of a flat panel display provided with an LED module according to a fourth embodiment of the present invention;

FIG. 8 is a perspective view of an assembled flat panel display provided with an LED module according to the fourth embodiment of the present invention;

FIG. 9 is a schematic diagram of an LED module according to the fourth embodiment of the present invention;

FIG. 10 is a cross-sectional view taken along line BB of FIG. 8.

### DETAILED DESCRIPTION OF THE INVENTION

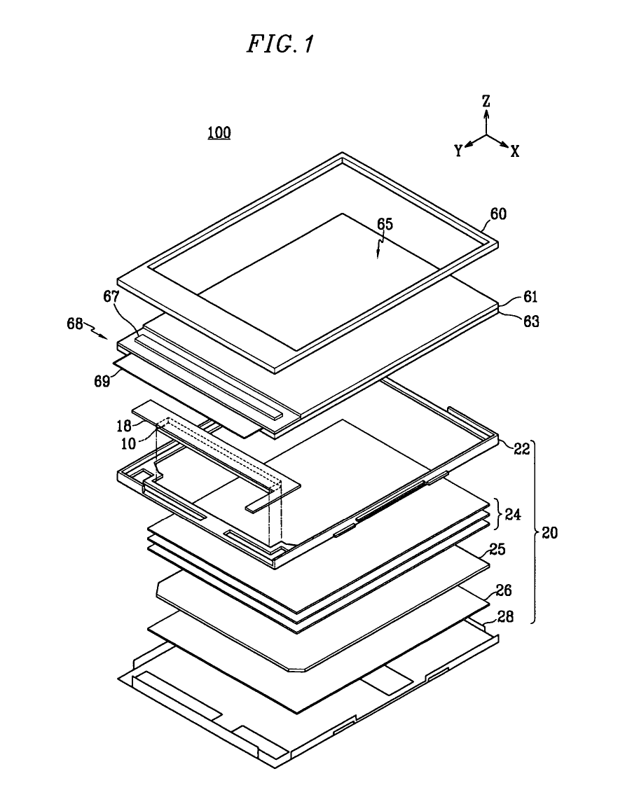

Hereinafter, exemplary embodiments of the present invention will be described with reference to the FIGS. 1 to 10. These embodiments of the present invention are merely exemplary embodiments of the present invention, and thus are not limited thereto.

FIG. 1 shows a flat panel display 100 provided with a LED module 10, which is used in a mobile product such as a cellular phone and so on.

The structure of the flat panel display 100 shown in FIG. 1 is merely an exemplary structure of the flat panel display of the present invention and the present invention is not limited to the structure of the flat panel display shown in FIG. 1. Therefore, it is possible to modify the structure of the flat panel display in other forms.

Although the panel unit 65 is shown as an LCD panel in FIG. 1, it is merely an example of a panel unit and the present invention is not limited to the LCD panel. Therefore, it is possible to use other panel unit instead of the LCD panel.

The panel assembly 68 includes a panel unit 65, an integrated circuit (IC) chip 67, and a flexible printed circuit (FPC) board 69.

The panel unit 65 displays image thereon and includes two panels 61 and 63. However, the panel unit 65 may include only one panel. An LCD, a representative of a non-emissive display device, usually includes two panels.

Hereinafter, the flat panel display 100 in embodiments of the present invention will be described as an LCD. However, the present invention is applicable to any kind of display device that requires light source.

The panel unit 65 includes a TFT (thin film transistor) array panel 63 including a plurality of TFTs, a color filter panel 61 disposed opposite the TFT array panel 63, and a liquid crystal layer (not shown) disposed between the two panels 61 and 63. The IC chip 67 is mounted on the TFT array panel 63, thereby controlling the panel unit 65.

The TFT array panel 63 includes a transparent glass substrate and a plurality of pixel electrodes (not shown), a plurality of TFTs (not shown), and a plurality of signal lines (not shown) formed on the substrate. The pixel electrodes are arranged in a matrix and made of transparent conductor such as indium tin oxide (ITO) and indium zinc oxide (IZO) or reflective metal such as Al and Ag. The signal lines includes gate lines (not shown) and data lines (not shown) and each TFT has a gate connected to one of the gate lines, a source connected to one of the data lines, and a drain connected to one of the pixel electrodes.

The data lines and the gate lines of the panel unit 65 are connected to the IC chip 67 and receive data signals and gate signals from the IC chip 67, respectively. The TFTs turn on or turn off in response to the gate signals from the gate lines to selectively transmit the data signals to the pixel electrodes.

On the other hand, the color filter panel 61 includes a plurality of color filters (not shown) facing the pixel electrodes and a common electrode (not shown) preferably made of transparent conductor such as ITO or IZO that covers the entire surface of the color filter panel 61. The common electrode is supplied with a common voltage and the voltage difference between the pixel electrode and the common electrode generate an electric field in the liquid crystal layer. The electric field determines orientations of liquid crystal molecules in the liquid crystal layer and thereby determines the transmittance of light passing through the liquid crystal layer. The FPC 69 transmits a plurality of control signals for controlling the IC chip 67.

The backlight assembly 20 is disposed under the LCD panel assembly 68 in order to uniformly provide a light to the LCD panel 65. The backlight assembly 20 is received in a bottom chassis 28.

The backlight assembly 20 includes an LED module 10 for providing light to the LCD panel 65, a circuit board 18 for supplying power to the LED module 10, an LGP 25 for guiding light emitted from the LED module 10 toward the LCD panel 65, a reflecting sheet 26 for reflecting the light passed through the LGP 25, and optical sheets 24 improving luminance of the light passed through the LGP 25 and supplying the light to the LCD panel 65.

A printed circuit board (not shown in FIG. 1) (hereinafter referred to as a “PCB”) is disposed at the back of the bottom chassis 28 and is electrically connected to the FPC board 69 for transmitting a driving signal to the LCD panel 65. In addition, the PCB is electrically connected to the circuit board 18 for supplying a power to drive the LED module 10.

The top chassis 60 is disposed over the panel assembly 68 to cover it. The top chassis 60 is not only assembled with the bottom chassis 28 but also bend the FPC 69 toward the outside of the mold frame 22. The panel assembly 68 is fixed between the top chassis 60 and the bottom chassis 28.

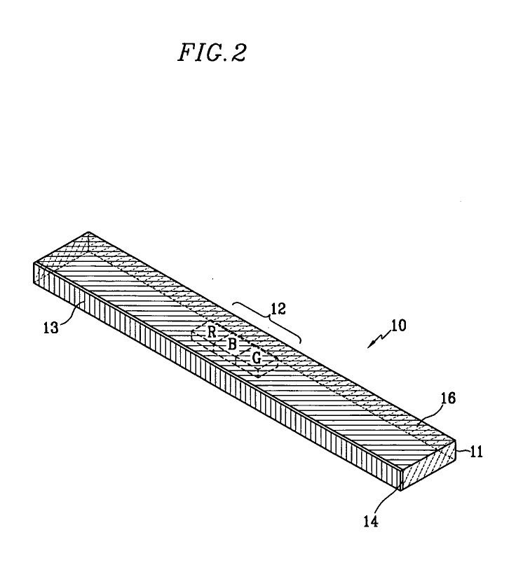

As shown in FIG. 1, the flat panel display 100 according to the first embodiment of the present invention includes the LED module 10 including a plurality of LEDs and a package enclosing them. In addition, the LED module 10 can include other elements if necessary. The LED module 10 will be further explained in detail with reference to FIG. 2.

FIG. 2 shows an LED module 10 according to the first embodiment of the present invention, which shows the LED module 10 shown in FIG. 1 rotated by an 180 degrees with respect to X-axis.

The LED module 10 includes a plurality of LEDs 12 and a package 11 enclosing them. There exist a plurality of gratings on the light emitting surface 13 of the package 11, thereby minimizing total reflection of light emitted from the LEDs 12. Furthermore, reflecting layers 16 (shown as hatched lines) are formed on at least one of surfaces of the package 11 which is adjacent to the light emitting surface 13 of it, thereby reflecting a light propagating toward an innerside of the LED 12 to the light emitting surface 13 of the package 11 and emitting the light therethrough. The reflecting layer 16 is also formed on a surface of the package 11 facing light emitting surface 13 of the package 11, thereby reflecting the light and emitting it toward the light emitting surface 13 of the package 11.

Considering that the flat panel display is used in a small-sized mobile product such as a cellular phone and so on, white light with desirable brightness can be obtained by only using a group of a red LED, a blue LED and a green LED. Although LEDs 12 are arranged in order of R(red), B(blue) and G(green) in the LED module 10, this is merely an example of the present invention and the present invention is not limited thereto. Therefore, LEDs can be arranged in another various methods. Furthermore, instead of using LEDs of three kinds of color, a blue LED and a yellow phosphor may be used together to form white light.

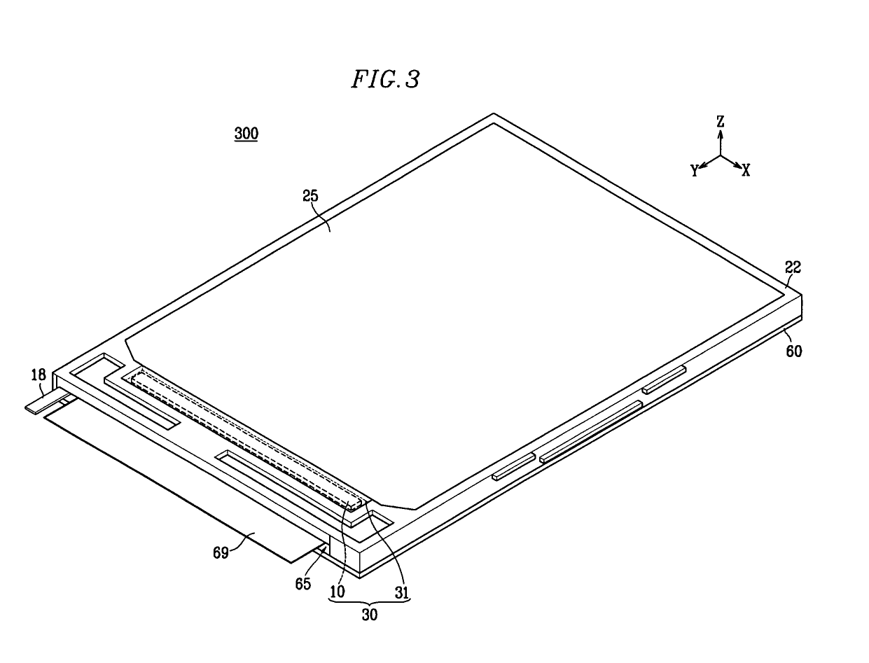

FIG. 3 shows another flat panel display provided with an LED module 30 according to the second embodiment of the present invention. FIG. 3 shows a flat panel display 300 omitting a reflecting sheet and a bottom chassis for convenience in order to show a modified LED module 30 covering with an index matching member 31.

The LED module 30 according to the second embodiment of the present invention is the same as the LED module according to a first embodiment of the present invention except the index matching member 31. In addition, the structure of a flat panel display 300 is the same as that of the flat panel display shown in FIG. 1 except the LED module 30. Therefore, the same element is referred to as same reference number and detailed explanation thereof is omitted for convenience.

As shown in FIG. 3, the LED module 30 covering with the index matching member 31 is adjacent to the LGP 25. Since the LED module 30 is adjacent to the LGP 25, the index matching member 31 minimizes loss of light therebetween.

For example, if a gap is formed between the LED module 30 and the LGP 25, loss of light occurs due to an air existing therebetween, which is caused by the difference between refractive indexes of the air and the LGP 25. The refractive index n₁ of the air is 0, and the refractive index n₂ of the LGP made of PMMA(polymethyl methacrylate) is about 1.5. Therefore, it is preferable to insert an index matching member between an LED module and the LGP. The index matching member has a refractive index which is between that of the air and LGP, thereby minimizing the difference between the refractive indexes of the air and LGP. Furthermore, it is more preferable to insert an index matching member having a refractive index which is more similar to that of the LGP considering the fact that an index matching member is inserted between the LED module and the LGP.

Taking these points into the consideration, it is desirable to choose an index matching member whose refractive index n₃ is over an average of the refractive index n₁ of the air and the refractive index n₂ of the LGP and is under the refractive index n₂ of the LGP. For example, glycerin can be chosen as an index matching member since its refractive index n₃ is about 1.46. The LED module 30 can be manufactured by applying a glycerin to the LED module 10 and hardening it by ultraviolet ray.

The relationship among the refractive index n₃ of the index matching member, the refractive index n₁ of the air, and the refractive index n₂ of the LGP may be described as the following Relation 1.
(n₁+n₂)/2<n₃≦n₂ [Relation 1]

More specifically, it is desirable that the refractive index n₃ of the index matching member 31 is set to be in the range from about 1.4 to about 1.5. If the refractive index n₃ is less than 1.4, there is a problem in that light is increasingly lost in proportion to an increasing reflectivity. On the contrary, since a general refractive index of the LGP is about 1.5, it is desirable that the refractive index n₃ of the index matching member does not exceed 1.5.

The loss of light is minimized by using an index matching member satisfying the conditions described above. Namely, the light emitted from the LED module 30 passes through the LGP 25 without the loss of light.

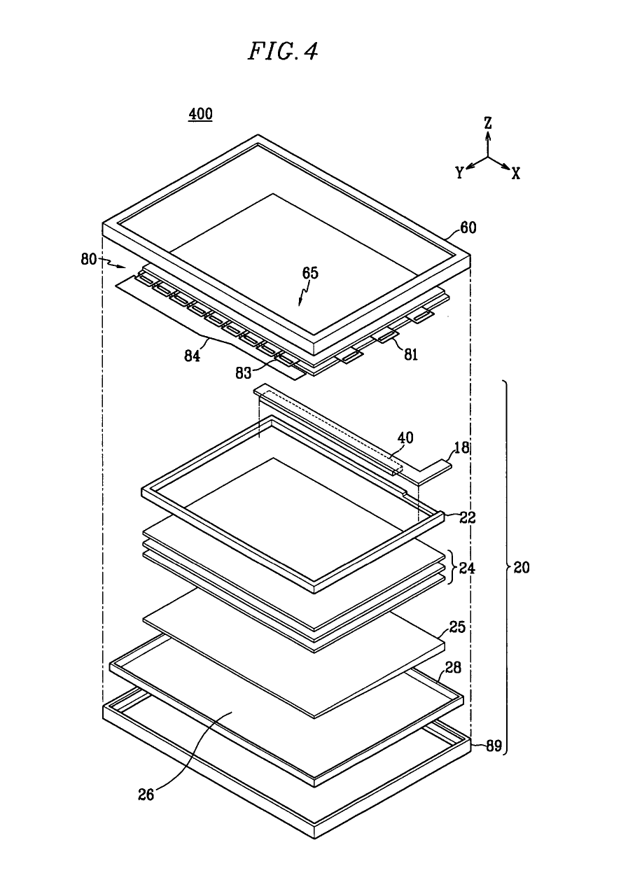

FIG. 4 is an exploded perspective view of a flat panel display 400 provided with an LED module 40 according to a third embodiment of the present invention. FIG. 4 shows the LED module 40 which is a kind of a line light source.

The LED module 40 can be applied to a middle-sized flat panel display such as a notebook computer and the elements included in the flat panel display 400 is similar to those included in the flat panel display shown in FIG. 1. Therefore, the same element is referred to as the same reference number and detailed explanation thereof is omitted for convenience. Accordingly, the different components of the flat panel display are mainly explained below.

The structure of the flat panel display shown in FIG. 4 is merely an exemplary structure of the flat panel display according to the present invention and the present invention is not limited thereto. Therefore, it is possible to modify the structure of the flat panel display in other forms.

As shown in FIG. 4, a flat panel display 400 includes a backlight assembly 20 for supplying light to an LCD panel 65 on which image is displayed. The backlight assembly 20 supplies and guides light to the LCD panel 65, and an LCD panel assembly 80 controls the LCD panel 65 in order to display image.

Although the LCD panel 65 is shown as a panel unit in FIG. 4, it is merely an example of a panel unit and the present invention is not limited thereto. Therefore, it is possible to use other panel units.

A plurality of driving integrated circuit packages 83, 81 are electrically connected to data lines and gate lines formed in the LCD panel 65, respectively. The driving integrated circuit package can be chip on film (COF), tape carrier package (TCP) and so on.

A plurality of data driving integrated circuit packages 83 are also electrically connected to the PCB 84 and transmits driving signals to the data lines formed in the LCD panel 65. In addition, a plurality of data driving integrated circuit packages 83 transmit driving signals to a plurality of gate driving integrated circuit package 81 through the LCD panel 65. Therefore, image can be displayed on the LCD panel 65.

The backlight assembly 20 includes an upper mold frame 22, lower mold frame 89 and a bottom chassis 28 to fix inner elements of a backlight assembly 20. The LED module 40 is received in the upper mold frame 22 and supplies light to the LGP 25. The LED module 40, optical sheets 24, the LGP 25 and a reflecting sheet 26 are received in the bottom chassis 28. The bottom chassis 28 is fixed in the lower mold frame 89.

Although not shown in FIG. 4, an inverter and a control board are disposed at the back of the bottom chassis 28. The inverter transforms the exterior power into a uniform level and then provides it with the LED module 40 through the circuit board 18. The control board converts analog data signal into digital data signal and transmits it to the LCD panel 65.

FIG. 5 shows a perspective view of a flat panel display 400 provided with an LED module 40, which assembles all the parts of the flat panel display 400 shown in FIG. 4. The LED module 40 extends along an X-axis direction.

As shown in an enlarged circle of FIG. 5, a plurality of LEDs 41 is arrayed in a package 42 along an X-axis direction. In FIG. 5, although the LEDs 41 are shown as an array in order of R, B, G, such diagram is merely an exemplary embodiment and the present invention is not limit thereto. Thus, it is possible to arrange the LEDs 41 in other forms. Since the electric connection between the LEDs 41 and its circuit board has been widely known to the skilled art in a technical field of the present invention, the detail explanation thereof is omitted.

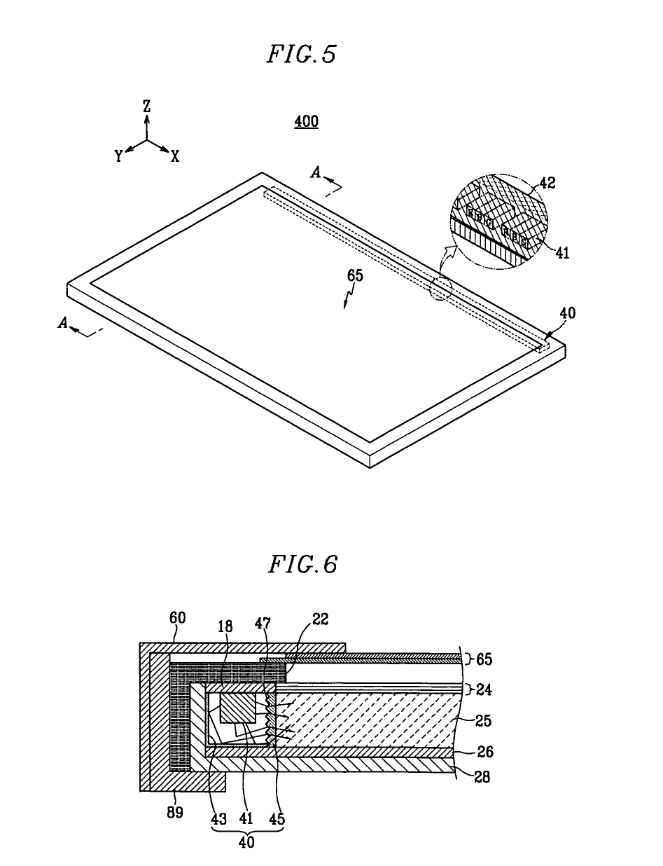

FIG. 6 shows a path of light which is emitted from the LED module 40 using an arrow. A reflecting layer 43 is partly formed on the inner surface of the package, thereby maximizing the amount of emitted light by reflecting light emitted from the LEDs 41. Therefore, it is possible to improve brightness as much as possible. A plurality of gratings 47 are formed on the light emitting surface of the LED module 40 for improving brightness more effectively. The light emitting surface provides a passage of the light from the LEDs 41.

A diffusion layer 45 is formed at the outer surface of the light emitting surface of the package, thereby effectively scattering the light emitted from the LEDs 41. Since the diffusion layer 45 is formed between the LEDs 41 and the LGP 25, more uniformly diffused light can be forwarded into the LGP 25 from the LEDs 41. On the contrary, the diffusion layer can be formed at the outer surface of the light emitting surface of the package.

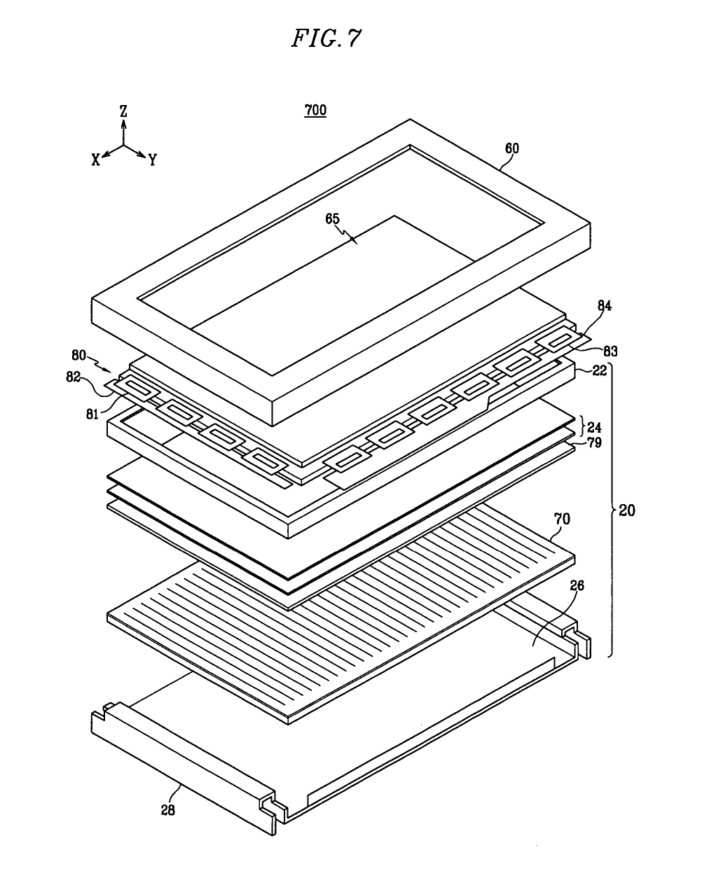

FIG. 7 shows a flat panel display 700 which is provided with an LED module 70 which is a kind of a planar light source. The LED module 70 according to a fourth embodiment of the present invention show in FIG. 7 can be applied to a large-sized flat panel display such as a LCD TV and so on.

In FIG. 7, since the basic structure of the flat panel display 700 is similar to that of the flat panel display shown in FIG. 4, the same elements are referred to as the same reference numbers and detailed explanations thereof are omitted.

The structure of the flat panel display shown in FIG. 7 is merely an exemplary structure of the flat panel display of the present invention and the present invention is not limited thereto. Therefore, it is possible to modify the structure of the flat panel display in other forms.

In addition, although the LCD panel 65 is shown as a panel unit in FIG. 7, it is merely an example of a panel unit and the present invention is not limited thereto. Therefore, it is possible to use other panel units.

As shown in FIG. 7, a flat panel display 700 includes an LCD panel 65 on which image is displayed and a backlight assembly 20 for supplying the light to the LCD panel 65. An LCD panel assembly 80 includes an LCD panel 65, driving integrated circuit package 81, 83, and PCBs 82, 84. A plurality of driving integrated circuit packages 81, 83 are electrically connected to gate lines and data lines formed on the LCD panel 65, respectively. The driving integrated circuit package can be chip on film, tape carrier package and so on.

The gate PCB 82 transmits gate driving signals to the LCD panel 65 through the gate driving integrated circuit packages 81 and the data PCB 84 transmits a data driving signals to the LCD panel 65 through the data driving integrated circuit packages 83.

A backlight assembly 20 is disposed below the LCD panel assembly 80 in order to provide the light to the LCD panel 65 on which image is displayed. Since the size of the LCD panel 65 is large, planar light source is indispensable to be provided in order to supply sufficient light to improve brightness. For improving brightness, a backlight assembly 20 also includes optical sheets 24, a diffusing plate 79 and a reflecting sheet 26. The light emitted from the LED module 70 is uniformly diffused when it is passed through the diffusing plate 79. In addition, the LED module 70 can get an improved brightness due to the optical sheets 24. The optical sheets 24, the diffusing plate 79, the LED module 70 and the reflecting sheet 26 are received in the bottom chassis 28 and are covered with the mold frame 22. Then, the backlight assembly 20 is fixed by the mold frame 22 and the bottom chassis 28.

FIG. 8 shows an assembled flat panel display 700 provided with an LED module which is a kind of a planar light source.

With the use of the LED module, it is possible to display image with high brightness on the LCD panel 65. In addition, since a single compacted LED module is used as a light source, it is possible to simplify manufacturing process and decrease the number of the components to be assembled.

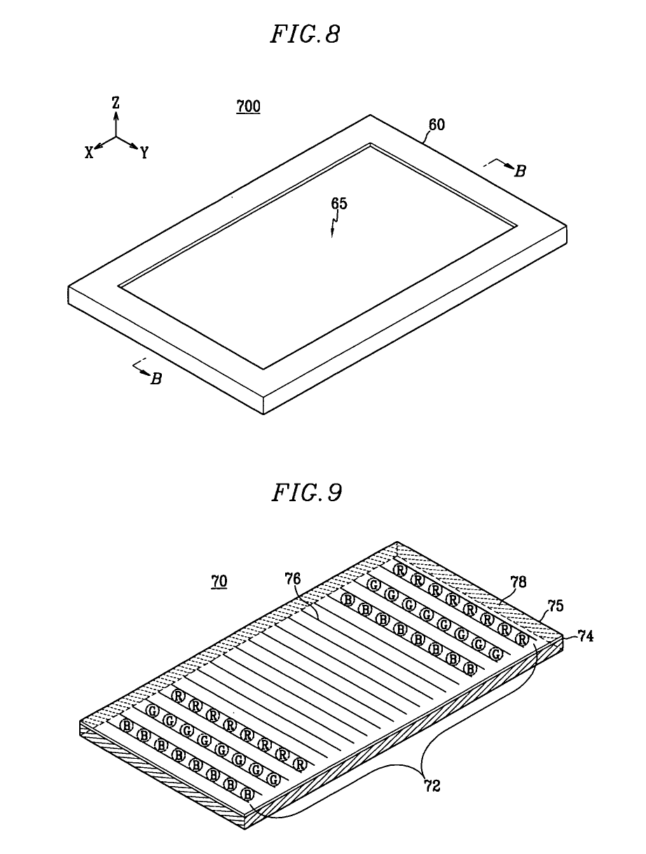

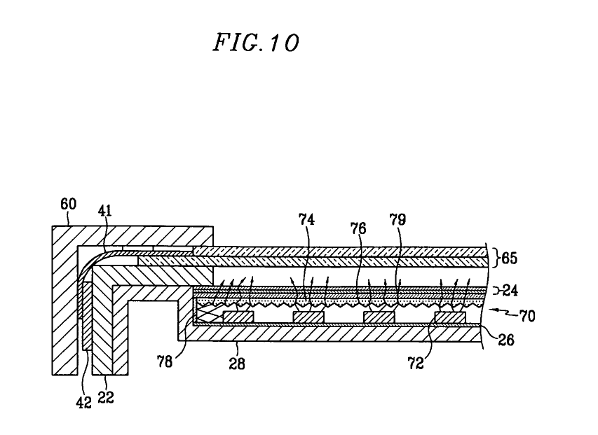

FIG. 9 shows a schematic diagram of an LED module 70 as a planar light source which is included in a flat panel display shown in FIG. 8.

As shown in FIG. 9, LED module 70 includes a plurality of LEDs 72 arrayed in a matrix. A plurality of LEDs 72 are enclosed in a package 75. The arranging pattern of the LEDs 72 shown in FIG. 9 is merely an example of the present invention and the present invention is not limited thereto. Thus, it is possible to arrange LEDs in various patterns.

The reflecting layers 78 (shown as hatched lines) are formed on at least one of surfaces adjacent to a light emitting surface 76 of the LED module 70, thereby reflecting the light emitted from the LEDs 72 and forwarding it to the light emitting surface 76. Therefore, loss of light is noticeably decreased.

In addition, since a plurality of gratings is formed on the light emitting surface 76 of the LED module 70, light can be effectively concentrated. Namely, due to a plurality of gratings, the light trapped in the LED module 70 caused by total reflection can be minimized. The diffusion layer 74 is formed on the outer surface of the light emitting surface 76, thereby regularly diffusing light. Although the diffusion layer 74 is formed on the LED module 70 as shown in FIG. 9, this is merely an example of the LED module of the present invention and the present invention is not limited thereto. Therefore, it is possible to exclude the diffusion layer 74 from the LED module 70 in some cases.

FIG. 10 shows a path of light emitted from the LED module 70 using an arrow.

As shown in FIG. 10 using arrows, the light emitted from the LEDs 72 is reflected by a reflecting layer 78 and forwarded to the diffusing plate 79. Since a diffusion layer 74 is coated at the outer surface of the light emitting surface 76, it is possible to mix the various colors of light at first. Next, the light is uniformly diffused in passing through the diffusing plate 79 enough not to represent a bright line on the LCD panel 65.

As described above, according to the present invention, there is an advantage in that the LED module can be manufactured as a line light source and a planar light source as well. Therefore, the LED module can be applied to the apparatus using middle-sized LCD or large-sized LCD. In addition, since the LED module is manufactured in a single form, thereby simplifying manufacturing process to assemble it and decreasing the number of the components to be assembled.

Since a plurality of gratings are formed on the light emitting surface of the package, the light trapped in the LED module caused by total reflection can be minimized.

Furthermore, a reflecting layer is formed on at least one of surfaces of the package adjacent to the light emitting surface of the package, thereby reflecting the light trapped in the LED module to the light emitting surface of the package and improving brightness.

Specifically, if a reflecting layer is formed on the surface of the package facing the light emitting surface, brightness can be more improved.

Since an inner surface or an outer surface of the light emitting surface of the package is covered with a diffusion layer, the colors of the light can be mixed effectively by diffusing light emitted from LEDs.

Specifically, the index matching member covering the LED module is adjacent to the LGP, thereby minimizing light reflection occurring between the LED module and the LGP.

Since the index n₃ of the index matching member is not less than an average of the index n₁ of the air and the index n₂ of the LGP and not more than the index n₂ of the LGP, it is possible to minimize loss of light when the light is forwarded into the LGP.

Further, the refractive index of the index matching member is set to be in the range from about 1.4 to about 1.5, thereby minimizing light reflection into the LED module.

The plurality of the LEDs is arrayed in a line, thereby being used in the middle-sized LCD such as a monitor and so on. Accordingly, the number of components of an LCD can be remarkably reduced and thus assembling process can be simplified.

In addition, the plurality of the LEDs is arrayed in a matrix, thereby being in the large-sized LCD such as a TV and so on.

Especially, the generation of bright lines is prevented using a diffusing plate disposed over the LED module.

Since a liquid panel unit is used as a panel unit, it is possible to directly apply the present invention.

Although embodiments of the present invention have been described, it is understood that various changes and modifications can be made by one skilled in the art within the spirit and scope of the present invention as hereinafter claimed.

1. A flat panel display comprising:
a panel unit displaying one or more images; and
a backlight assembly that includes a light emitting diode module supplying a light to the panel unit and guides the light to the panel unit,
wherein the light emitting diode module includes a plurality of light emitting diodes that emits light and a package that encloses the light emitting diodes and has a light emitting surface providing a passage of the light from the light emitting diodes and having a plurality of gratings formed thereon.

2. The flat panel display of claim 1, further comprising a reflecting layer formed on at least one of the surfaces of the package adjacent to the light emitting surface of the package.

3. The flat panel display of claim 1, further comprising a reflecting layer formed on a surface of the package facing the light emitting surface of the package.

4. The flat panel display of claim 1, further comprising a diffusion layer formed on inner or outer surface of the light emitting surface of the package.

5. The flat panel display of claim 1, further comprising:
an index matching member coated on an outer surface of the light emitting surface of the package; and
a light guiding plate which is disposed adjacent to the index matching member.

6. The flat panel display of claim 5, wherein a refractive index n₃ of the index matching member satisfies a relation (n₁+n₂)/2<n₃≦n₂, wherein n₁ is a refractive index of air and n₂ is a refractive index of the light guiding plate.

7. The flat panel display of claim 6, wherein the refractive index of the index matching member is in the range of about 1.4 to about 1.5.

8. The flat panel display of claim 1, wherein the plurality of light emitting diodes are arrayed in a line.

9. The flat panel display of claim 8, further comprising a reflecting layer formed on at least one of surfaces of the package adjacent to the light emitting surface of the package.

10. The flat panel display of claim 8, further comprising a reflecting layer formed on a surface of the package facing the light emitting surface of the package.

11. The flat panel display of claim 8, further comprising a diffusion layer formed on inner or outer surface of the light emitting surface of the package.

12. The flat panel display of claim 1, wherein the plurality of light emitting diodes are arrayed in a matrix.

13. The flat panel display of claim 12, wherein the backlight assembly further comprises a diffusing plate disposed over the light emitting diode module.

14. The flat panel display of claim 12, further comprising a reflecting layer formed on at least one of surfaces of the package adjacent to the light emitting surface of the package.

15. The flat panel display of claim 12, further comprising a reflecting layer formed on a surface of the package facing the light emitting surface of the package.

16. The flat panel display of claim 12, further comprising a diffusion layer formed on inner or outer surface of the light emitting surface of the package.

17. The flat panel display of claim 12, wherein the panel unit is a liquid crystal panel unit.

18. A light emitting diode module comprising:
a plurality of light emitting diodes emitting light; and
a package enclosing the light emitting diodes,
wherein the package has a light emitting surface providing a passage of the light from the light emitting diodes and has a plurality of gratings formed thereon.

19. The light emitting diode module of claim 18, further comprising a reflecting layer formed on at least one of surfaces of the package adjacent to the light emitting surface of the package.

20. The light emitting diode module of claim 18, further comprising a reflecting layer formed on a surface of the package facing the light emitting surface of the package.

21. The light emitting diode module of claim 18, further comprising a diffusion layer formed on inner or outer surface of the light emitting surface of the package

22. The light emitting diode module of claim 18, wherein the plurality of light emitting diodes are arrayed in a line.

23. The light emitting diode module of claim 18, wherein the plurality of light emitting diodes are arrayed in a matrix.
